(19) United States
(12) Patent Application Publication
(10) Pub. No.: US 2019/0120881 A1
(43) Pub. Date: Apr. 25, 2019

(54) BROWN OUT DETECTOR WITH HYSTERESIS SPECIFICITY

(71) Applicant: AIRPOINT CO., LTD., Daejeon (KR)

(72) Inventor: Jung-Hoon YOO, Gyeonggi-do (KR)

(21) Appl. No.: 16/159,165

(22) Filed: Oct. 12, 2018

(30) Foreign Application Priority Data
Oct. 20, 2017 (KR) 10-2017-0136913

(51) Int. Cl. G01R 19/165; H03K 3/3565; H03K 5/24; H03K 17/30; H03K 17/22; G06F 1/28

(52) U.S. Cl. CPC G01R 19/16552; H03K 3/3565; G06F 1/28; H03K 17/302; H03K 17/223; H03K 5/2472

(57) ABSTRACT

A brown out detector (BOD) may include: a first reference voltage comparison unit configured to generate a first comparison signal by comparing the supply voltage to a first reference voltage; a second reference voltage comparison unit configured to generate a second comparison signal by comparing the supply voltage to a second reference voltage; a hysteresis comparator configured to generate a signal for suspending the operation of the external system when the supply voltage drops below the first reference voltage, and generate a signal for maintaining or resuming the operation of the external system when the supply voltage rises over the second reference voltage, based on the first and second comparison signals; and a reference voltage decider configured to control on/off of the first and second reference voltage comparison units based on an output signal of the hysteresis comparator.

### BACKGROUND

### Technical Field

The present disclosure relates to a brown out detector (BOD), and more particularly, to the BOD for varying a reference voltage depending on a state of a brown-out detection signal using a hysteresis comparator, thereby stably detecting when a supply voltage becomes equal to or lower than a lower limit level.

### Related Art

In general, a voltage supplied to a micro controller unit (MCU) may become unstable for the various reasons such as a rebooting process of a product due to a blackout or spark caused by a change of external factors. In order to prevent a malfunction of the MCU, the BOD may sense when the voltage supplied to the MCU becomes equal to or lower than a predetermined voltage, and suspend the operation of the MCU by providing a brown-out detection signal to the MCU when a level of the supplied voltage is equal to or less than the predetermined voltage level.

For the conventional BOD in a noisy environment, since when the supplied voltage level is lower to about a level of reference voltage, the supplied voltage level may oscillate around the reference voltage level due to the interference of the noise, an output signal of the BOD may alternate repeatedly between a high state and a low state. Recently, a low voltage is supplied to electronic devices in many cases. Thus, the electronic devices are easily exposed to noise when driven at a low voltage. Therefore, the reference voltage needs to be set depending on an output signal of the BOD to stably operate it.

### SUMMARY

Various embodiments are directed to a brown out detector (BOD) which can differently generate a reference voltage depending on a state of a brown-out detection signal using a hysteresis comparator, thereby normally operating even in the noisy environment. Also, various embodiments are directed to a BOD which can generate a variety of divided voltages using a voltage divider, and adjust a supply voltage at which the BOD is operated, depending on a situation.

In an embodiment, there is provided a BOD which detects a state of a supply voltage provided to an external system and controls an operation of the external system. The BOD may include: a first reference voltage comparison unit configured to generate a first comparison signal by comparing the supply voltage to a preset first reference voltage; a second reference voltage comparison unit configured to generate a second comparison signal by comparing the supply voltage to a preset second reference voltage; a signal output unit configured to generate a signal for suspending the operation of the external system when the supply voltage drops below the first reference voltage, and generate a signal for maintaining or resuming the operation of the external system when the supply voltage rises over the second reference voltage, based on the first and second comparison signals; and a reference voltage decider configured to control on/off of the first and second reference voltage comparison units based on an output signal of the signal output unit. The second reference voltage may have a higher level by a hysteresis voltage than the first reference voltage.

### BRIEF DESCRIPTION OF THE DRAWINGS

FIG. 1 is a block diagram illustrating a brown out detector (BOD) with a hysteresis specificity in accordance with an embodiment of the present invention.

FIG. 2 illustrates a high state or low state of a brown-out detection signal of the BOD with a hysteresis specificity in accordance with the embodiment of the present invention.

FIG. 3 is a detailed circuit diagram illustrating a voltage divider of the BOD with a hysteresis specificity in accordance with the embodiment of the present invention.

### DETAILED DESCRIPTION

The above-described purpose, features and advantages will be clarified through the following embodiments with reference to the accompanying drawings.

The descriptions of specific structures or functions are made only to describe embodiments according to the concept of the present invention. The concept of the present invention may be embodied in various manners, and the present invention is not limited to the embodiments described in this specification.

Since the embodiments according to the concept of the present invention can be modified in various manners and have various forms, specific embodiments will be illustrated in the drawings and described in detail in this specification. However, the embodiments according to the concept of the present invention are not limited to the specific embodiments, but may include all modifications, equivalents and substitutions without departing from the sprit and scope of the present invention.

When an element is referred to as being “coupled” or “connected” to another element, it may not only indicate that the former element is directly coupled or connected to the latter element, but also indicate that another element is present therebetween. On the other hand, when an element is referred to as being “directly coupled” or “directly connected” to another element, it may indicate that no element is present therebetween. Other expressions for describing the relations between elements, such as “between”, “immediately between”, “adjacent to”, and “directly adjacent to”, should be analyzed in the same manner.

All terms used in this specification are used only to describe a specific embodiment, and do not limit the present invention. The terms of a singular form may include plural forms unless referred to the contrary. In this specification, the meaning of a term “include” or “have” specifies a property, number, step, operation, element, part or combinations thereof, but does not exclude one or more other properties, numbers, steps, operations, elements, parts or combinations thereof.

All terms used herein have the same meanings as those understood by a person skilled in the art to which the present invention pertains, as long as the terms are differently defined. Terms having the same meanings as those defined in a generally used dictionary should be analyzed to have meanings which coincide with contextual meanings in the related art, and not analyzed as ideal or excessively formal meanings.

Hereafter, exemplary embodiments of the prevent invention will be described in detail with reference to the accompanying drawings. Like reference numerals in the drawings represent the same members.

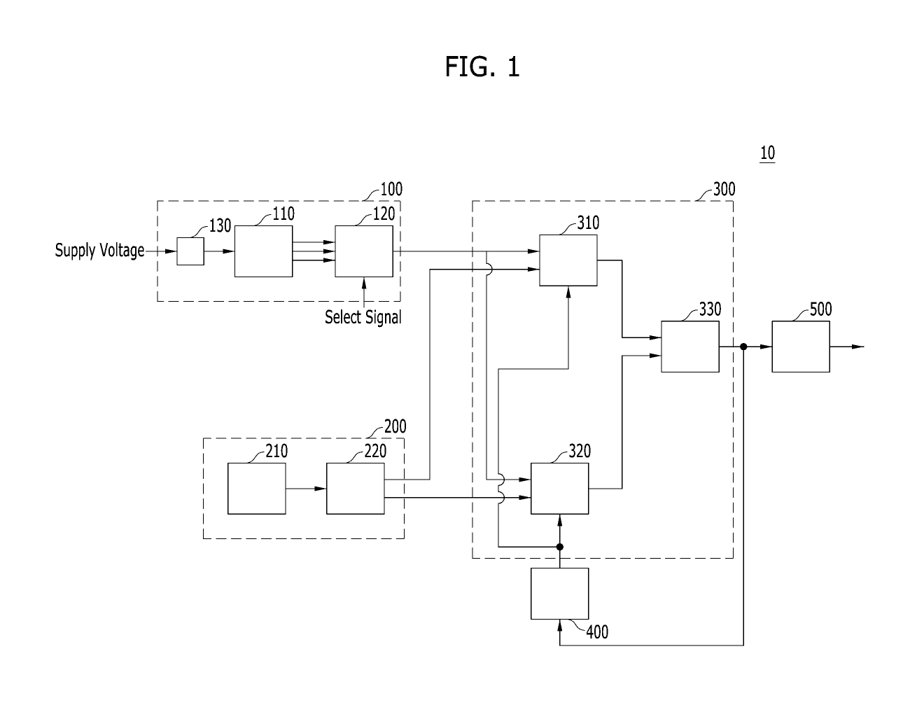

FIG. 1 is a block diagram illustrating a brow out detector (BOD) with a hysteresis specificity in accordance with an embodiment of the present invention. In FIG. 1, the BOD 10 with a hysteresis specificity includes a voltage divider 100, a reference voltage generator 200, a hysteresis comparator 300, a reference voltage decider 400 and a signal delay unit 500.

The voltage divider 100 includes a voltage division unit 110, a divided voltage selection unit 120 and a circuit switching unit 130. The voltage division unit 110 divides a supply voltage supplied to an external system such as a micro controller unit (MCU) into a plurality of supply voltages, the divided voltage selection unit 120 selects one divided voltage among the plurality of divided supply voltages, and the circuit switching unit 130 opens the circuit to block the supply voltage applied to the voltage divider 100, when the BOD 10 is not operated.

The reference voltage generator 200 includes a reference voltage generation unit 210 and a hysteresis generation unit 220. The reference voltage generation unit 210 generates a preset reference voltage, and the hysteresis generation unit 220 generates first and second reference voltages from the reference voltage generated through the reference voltage generation unit 210, based on a preset hysteresis voltage value. The reference voltage generation unit 210 may generate the reference voltage of about 1.2V, for example.

The hysteresis comparator 300 includes a first reference voltage comparison unit 310, a second reference voltage comparison unit 320 and a signal output unit 330. The first reference voltage comparison unit 310 generates a first comparison signal by comparing one divided voltage selected through the divided voltage selection unit 120 to the first reference voltage, the second reference voltage comparison unit 320 generates a second comparison signal by comparing the divided voltage selected through the divided voltage selection unit 120 to the second comparison signal, and the signal output unit 330 outputs a high brown-out detection signal or a low brown-out detection signal depended on the first and second comparison signals. The reference voltage decider 400 turns on/off the first and second reference voltage comparison units 310 and 320 depending on the state of the brown-out detection signal of the signal output unit 330.

The signal delay unit 500 serves to delay the time point at which the low brown-out detection signal transitions to the high brown-out detection signal by a predetermined time.

Therefore, the signal delay unit 500 delays the detection signal until the voltage at which the external system can operate is applied, such that the suspended state of the external system is maintained. Thus, the external system can stably operate.

Since there are many commercialized products which can be used as the reference voltage generator 200 and the signal delay unit 500, the detailed descriptions thereof will be omitted herein.

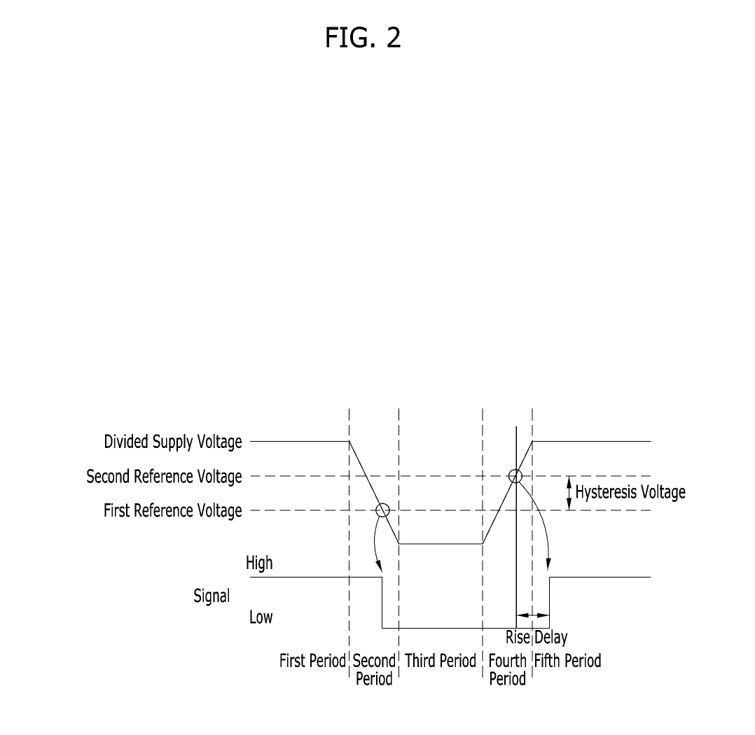

FIG. 2 illustrates the high state or low state of the brown-out detection signal of the BOD with a hysteresis specificity in accordance with the embodiment of the present invention. Referring to FIG. 2, the overall operations of the BOD 10 with a hysteresis specificity in accordance with the embodiment of the present invention will be described.

In the initial state, the BOD 10 maintains operation of the external system, for example. That is, the high brown-out detection signal maintains the operation of the external system, and the low brown-out detection signal is an active low signal to suspend the external system.

First, when a supply voltage of the external system is inputted to the voltage division unit 110, the voltage division unit 110 divides the supply voltage into a plurality of supply voltages. The divided voltage selection unit 120 selects one divided voltage among the plurality of divided supply voltages, depended on a select signal, and provides the selected divided supply voltage to the first and second reference voltage comparison units 310 and 320. The select signal may be defined and inputted according to a designer's intention.

The reference voltage generation unit 210 generates the preset reference voltage. The hysteresis generation unit 220 receives the preset reference voltage from the reference voltage generation unit 210, and generates the first and second reference voltages from the preset reference voltage, depended on the preset hysteresis voltage value. The hysteresis voltage value may indicate a voltage difference between the first and second reference voltages. That is, the hysteresis generation unit 220 can output the first reference voltage or the second reference voltage depending on the reference voltage applied from the reference voltage generation unit 210. The first reference voltage is decreased by a half of the hysteresis voltage value at the reference voltage, the second reference voltage is increased by the half of the hysteresis voltage value at the reference voltage.

When the brown-out detection signal from the signal output unit 330 described later is high, the reference voltage decider 400 turns on the first reference voltage comparison unit 310, and turns off the second reference voltage comparison unit 320.

On the other hand, when the brown-out detection signal from the signal output unit 330 is low, the reference voltage decider 400 turns off the first reference voltage comparison unit 310, and turns on the second reference voltage comparison unit 320.

The first comparison signal outputted from the first reference voltage comparison unit 310 or the second comparison signal outputted from the second reference voltage comparison unit 320 is provided to the signal output unit 330.

The signal output unit 330 is inputted the first comparison signal from the first reference voltage comparison unit 310 and generates the low brown-out detection signal when the divided voltage is lower than the first reference voltage, or is inputted the second comparison signal from the second reference voltage comparison unit 320 and generates the high brown-out detection signal when the divided voltage is higher than the second reference voltage.

The signal delay unit 500 is inputted the detection signal from the signal output unit 330, and delays the time point at which the low brown-out detection signal transitions to the high brown-out detection signal by predetermined time to provide the detection signal to the external system.

Hereafter, the operation of the hysteresis comparator 300 will be described in more detail with reference to FIG. 2.

In the initial state, the reference voltage decider 400 turns on the first reference voltage comparison unit 310, and turns off the second reference voltage comparison unit 320. The first reference voltage comparison unit 310 compares the divided voltage and the first reference voltage, and outputs a high or low signal depending on the comparison result. In the initial state, the supply voltage provided to the external system may have a high level. Therefore, since the divided voltage is higher than the first reference voltage in the initial state, the first reference voltage comparison unit 310 provides a high signal to the signal output unit 330. When the high signal is inputted from the first reference voltage comparison unit 310, the signal output unit 330 generates the high brown-out detection signal, and provides the high brown-out detection signal to the signal delay unit 500. The signal delay unit 500 supplies the brown-output detection signal is inputted from the signal output unit 330 to the external system, for example, the MCU.

The high brown-out detection signal provided to the external system from the signal delay unit 500 maintains the normal operation state of the external system.

The high brown-out detection signal outputted from the signal output unit 330 is also provided to the reference voltage decider 400. When the high brown-out detection signal is applied, the reference voltage decider 400 maintains the on-state of the first reference voltage comparison unit 310 and the off-state of the second reference voltage comparison unit 320.

Then, when the divided voltage is lower than the first reference voltage in a second period as illustrated in FIG. 2, the first reference voltage comparison unit 310 provides a low signal to the signal output unit 330.

When the low signal is inputted from the first reference voltage comparison unit 310, the signal output unit 330 generates the low brown-out detection signal, and provides the low brown-out detection signal to the external system through the signal delay unit 500.

The low brown-out detection signal provided to the external system from the signal output unit 330 suspends the operation of the external system.

Then, as illustrated in FIG. 2, the low brown-out detection signal from the signal output unit 330 is provided to the reference voltage decider 400. When the low brown-out detection signal is inputted, the reference voltage decider 400 turns off the first reference voltage comparison unit 310, and turns on the second reference voltage comparison unit 320. The second reference voltage comparison unit 320 compares the divided voltage and the second reference voltage, and outputs a high or low signal depending on the comparison result. In a third period, the supply voltage provided to the external system may have a low level. Therefore, since the divided voltage is lower than the second reference voltage in the third period, the second reference voltage comparison unit 320 provides a low signal to the signal output unit 330. When the low signal is inputted from the second reference voltage comparison unit 320, the signal output unit 330 generates the low brown-out detection signal, and provides the low brown-out detection signal to the external system through the signal delay unit 500.

The low brown-out detection signal maintains the operation suspended state of the external system.

Then, when the divided voltage is higher than the second reference voltage in a fourth period as illustrated in FIG. 2, the second reference voltage comparison unit 320 provides a high signal to the signal output unit 330.

When the high signal is inputted from the second reference voltage comparison unit 320, the signal output unit 330 generates the high brown-out detection signal, and provides the high brown-out detection signal to the signal delay unit 500. When the signal transitions from the low state to the high state, the signal delay unit 500 delays the low brown-out detection signal by the predetermined time, and outputs the delayed brown-out detection signal. Then, the signal delay unit 500 changes the brown-out detection signal to a high state, and outputs the high brown-out detection signal.

The external system resumes the operation when the high-state brown-output detection signal is applied from the signal delay unit 500.

The overall operations of the above-described BOD 10 may be exemplified as follows. When the reference voltage of the reference voltage generation unit 210 is 1.2V and the hysteresis voltage value is 0.02V, the first reference voltage generated by the hysteresis generation unit 220 becomes 1.19V which is lowered by 0.01 corresponding to the half of the hysteresis voltage value at the reference voltage, and the second reference voltage generated by the hysteresis generation unit 220 becomes 1.21V which is increased by 0.01V corresponding to the half of the hysteresis voltage value at the reference voltage.

Since the divided voltage is maintained at more than the first reference voltage of 1.19V in the initial state, the high brown-out detection signal is generated at the signal output unit 330. When the divided voltage is lower than the first reference voltage of 1.19V or less in the second period, the low brown-out detection signal is generated at the signal output unit 330.

Then, since the divided voltage is maintained at less than the second reference voltage of 1.21V in the third period, the low brown-out detection signal is generated at the signal output unit 330. When the divided voltage is higher than the second reference voltage of 1.21V or more in the fourth period, the high brown-out detection signal is generated at the signal output unit 330. The high brown-out detection signal is delayed by the predetermined time by the signal delay unit 500, and then provided to the external system.

Therefore, when the divided voltage oscillates between the first reference voltage of 1.19V and the second reference voltage of 1.21V due to interference of noise after dropping below the first reference voltage level, the BOD 10 can retain the low brown-out detection signal. When the divided voltage oscillates between the first reference voltage of 1.19V and the second reference voltage of 1.21V due to interference of noise after rising over the second reference voltage level, the BOD 10 can retain the high brown-out detection signal. Thus, the BOD 10 can stably operate without being affected by interference of noise.

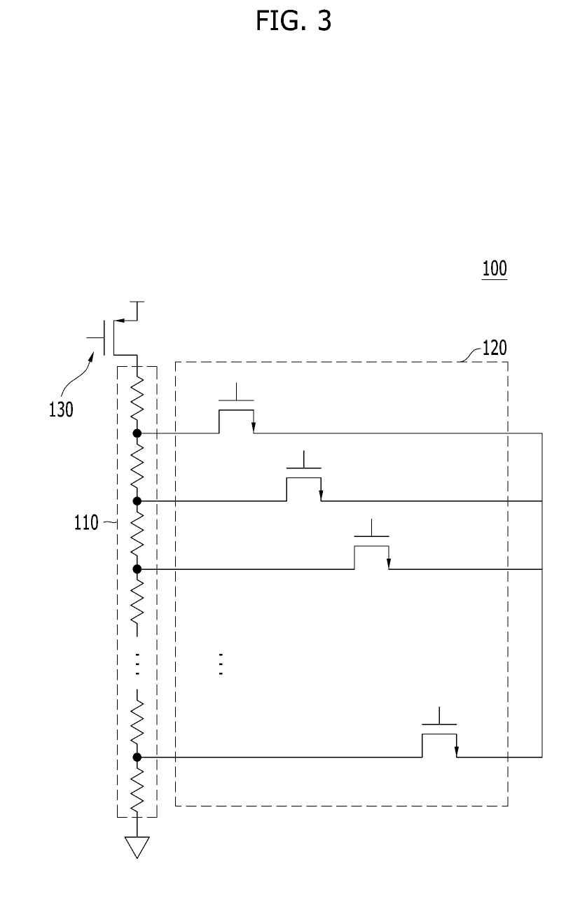

FIG. 3 is a detailed circuit diagram illustrating the voltage divider 100 of the BOD 10 with a hysteresis specificity in accordance with the embodiment of the present invention. In FIG. 3, the voltage divider 100 may include the voltage division unit 110, the divided voltage selection unit 120 and the circuit switching unit 130.

The voltage supplied to the voltage divider unit 110 is divided by a plurality of resistors, and applied to the divided voltage selection unit 120. Therefore, the values of the divided supply voltages may differ depending on the resistance values of the respective resistors.

As described above, the divided voltage selection unit 120 selects one divided voltage among the plurality of divided supply voltages depended on the select signal, and provides the selected divided voltage to the first and second reference voltage comparison units 310 and 320. An analog multiplexer may be used as the divided voltage selection unit 120. The analog multiplexer is inputted the select signal from a program designed by a designer. Referring to FIG. 3, the supply voltage is divided among the plurality of resistors and then applied. Therefore, according to the select signal, one or more resistors may be selected among the plurality of resistors, such that the analog multiplexer selects a voltage corresponding to a divided voltage preset by the designer among the plurality of divided supply voltages, and a circuit connected to the one or more resistors may be switched to select the voltage corresponding to the divided voltage preset by the designer.

For example, when the divider ratio is 1:1 and the supply voltage is 3.3V, a divided voltage of 1.65V corresponding to the half of the supply voltage may be generated. When the supply voltage is lower than 2.4V, the divided voltage may become 1.2V or less. When the divider ratio is 2:1 and the supply voltage is 3.3V, divided voltages are 2.2V and 1.1V, respectively. When the analog multiplexer is used, the signal selected from two divided voltages, depending on the select signal inputted to the analog multiplexer from outside, may be input to the first and second reference voltage comparison units 310 and 320.

The circuit switching unit 130 may open the circuit to block the supply voltage from being applied to the voltage divider 100 when the BOD 10 is not operated, and connect the circuit to apply the supply voltage to the voltage divider 100 when the BOD 10 is operated. The circuit switching unit 130 may include an enable pin.

In accordance with the embodiment of the present invention, the BOD can differently generate the reference voltage depending on the state of the brown-out detection signal using the hysteresis comparator, thereby stably operating in reference voltage ranges which are differently set. Therefore, the BOD can normally operate even in the noisy environment.

Furthermore, the BOD can generate the plurality of divided supply voltages using the voltage divider, and the hysteresis comparator can compare any one of the plurality of divided supply voltages to the reference voltage, and determine whether to output the output signal of the BOD. Therefore, the operation of the BOD can be controlled according to a variety of situations.

While various embodiments have been described above, it will be understood to those skilled in the art that the embodiments described are by way of example only. Accordingly, the disclosure described herein should not be limited based on the described embodiments.

1. A brown out detector (BOD) which detects a state of a supply voltage provided to an external system and controls an operation of the external system, the BOD comprising:
a first reference voltage comparison unit configured to generate a first comparison signal by comparing the supply voltage to a preset first reference voltage;
a second reference voltage comparison unit configured to generate a second comparison signal by comparing the supply voltage to a preset second reference voltage;
a signal output unit configured to generate a signal for suspending the operation of the external system when the supply voltage is lower than the first reference voltage, and generate a signal for maintaining or resuming the operation of the external system when the supply voltage is higher than the second reference voltage, depended on the first and second comparison signals; and
a reference voltage decider configured to control on/off of the first and second reference voltage comparison units depended on an output signal of the signal output unit,
wherein the second reference voltage has a higher level by a hysteresis voltage than the first reference voltage.

2. The BOD of claim 1, further comprising:
a reference voltage generation unit configured to generate a preset reference voltage; and
a hysteresis generation unit configured to generate the first and second reference voltages from the reference voltage generated by the reference voltage generation unit, based on the preset hysteresis voltage value.

3. The BOD of claim 1, further comprising:
a voltage division unit configured to receive the supply voltage from outside, and divide the supply voltage into a plurality of supply voltages; and
a divided voltage selection unit configured to select one divided voltage among the plurality of divided supply voltages and input the selected divided voltage to the first and second reference voltage comparison units.

4. The BOD of claim 1, further comprising a circuit switching unit configured to open a circuit to block the supply voltage from being applied to the voltage division unit when the BOD is not operated, and connect the circuit to apply the supply voltage to the voltage division unit when the BOD is operated.

5. The BOD of claim 1, further comprising a signal delay unit configured to receive the signal for suspending the operation of the external system or the signal for maintaining or resuming the operation of the external system from the signal output unit, delay the signal for suspending the operation of the external system by a predetermined time when the signal for suspending the operation of the external system transitions to the signal for maintaining or resuming the operation of the external system, then change the signal for suspending the operation of the external system to the signal for maintaining or resuming the operation of the external system, and output the signal for maintaining or resuming the operation of the external system.

6. The BOD of claim 1, wherein the divided voltage selection unit comprises an analog multiplexer configured to programmably select one divided voltage among the plurality of divided supply voltages through a select signal preset by a designer, and input the selected divided voltage to the first and second reference voltage comparison units.

7. The BOD of claim 1, wherein the reference voltage decider turns off the first reference voltage comparison unit and turns on the second reference voltage comparison unit, when the signal for suspending the operation of the external system is received, or turns on the first reference voltage comparison unit and turns off the second reference voltage comparison unit, when the signal for maintaining or resuming the operation of the external system is received.

8. The BOD of claim 2, wherein the divided voltage selection unit comprises an analog multiplexer configured to programmably select one divided voltage among the plurality of divided supply voltages through a select signal preset by a designer, and input the selected divided voltage to the first and second reference voltage comparison units.

9. The BOD of claim 3, wherein the divided voltage selection unit comprises an analog multiplexer configured to programmably select one divided voltage among the plurality of divided supply voltages through a select signal preset by a designer, and input the selected divided voltage to the first and second reference voltage comparison units.

10. The BOD of claim 4, wherein the divided voltage selection unit comprises an analog multiplexer configured to programmably select one divided voltage among the plurality of divided supply voltages through a select signal preset by a designer, and input the selected divided voltage to the first and second reference voltage comparison units.

11. The BOD of claim 5, wherein the divided voltage selection unit comprises an analog multiplexer configured to programmably select one divided voltage among the plurality of divided supply voltages through a select signal preset by a designer, and input the selected divided voltage to the first and second reference voltage comparison units.

12. The BOD of claim 2, wherein the reference voltage decider turns off the first reference voltage comparison unit and turns on the second reference voltage comparison unit, when the signal for suspending the operation of the external system is received, or turns on the first reference voltage comparison unit and turns off the second reference voltage comparison unit, when the signal for maintaining or resuming the operation of the external system is received.

13. The BOD of claim 3, wherein the reference voltage decider turns off the first reference voltage comparison unit and turns on the second reference voltage comparison unit, when the signal for suspending the operation of the external system is received, or turns on the first reference voltage comparison unit and turns off the second reference voltage comparison unit, when the signal for maintaining or resuming the operation of the external system is received.

14. The BOD of claim 4, wherein the reference voltage decider turns off the first reference voltage comparison unit and turns on the second reference voltage comparison unit, when the signal for suspending the operation of the external system is received, or turns on the first reference voltage comparison unit and turns off the second reference voltage comparison unit, when the signal for maintaining or resuming the operation of the external system is received.

15. The BOD of claim 5, wherein the reference voltage decider turns off the first reference voltage comparison unit and turns on the second reference voltage comparison unit, when the signal for suspending the operation of the external system is received, or turns on the first reference voltage comparison unit and turns off the second reference voltage comparison unit, when the signal for maintaining or resuming the operation of the external system is received.
